(19) United States
(12) Patent Application Publication
(10) Pub. No.: US 2023/0178561 A1
(43) Pub. Date: Jun. 8, 2023

(54) ACTIVE MATRIX SUBSTRATE AND METHOD FOR MANUFACTURING SAME

(71) Applicant: Sharp Display Technology Corporation, Kameyama City (JP)

(72) Inventors: Hideki KITAGAWA, Kameyama City (JP); Yoshimasa CHIKAMA, Kameyama City (JP); Masamitsu YAMANAKA, Kameyama City (JP)

(21) Appl. No.: 18/074,551

(22) Filed: Dec. 5, 2022

Related U.S. Application Data
(60) Provisional application No. 63/286,639, filed on Dec. 7, 2021.

(51) Int. Cl. H01L 27/12

(52) U.S. Cl. CPC H01L 27/1225; H01L 27/124; H01L 27/127

(57) ABSTRACT

An active matrix substrate includes a substrate, a plurality of thin-film transistors, a plurality of pixel electrodes, and a first insulating layer. Each pixel electrode is formed from a transparent conducting material. Each thin-film transistor includes a gate electrode, a gate insulating layer, source and drain electrodes, and an oxide semiconductor layer. The oxide semiconductor layer includes a channel region, a source contact region, and a drain contact region. The source electrode has a stack structure including a source transparent conducting layer and a source metal layer. The drain electrode includes a drain transparent conducting layer. The drain transparent conducting layer is formed integrally with a corresponding one of the plurality of pixel electrodes.

### BACKGROUND

### 1. Field

The present disclosure relates to an active matrix substrate and a method for manufacturing the same.

### 2. Description of the Related Art

An active matrix substrate that is used is a liquid crystal display device or other devices includes a switching element such as a thin-film transistor (hereinafter referred to as “TFT”) for each pixel. As such a switching element, a TFT having an amorphous silicon film as an active layer (hereinafter referred to as “amorphous silicon TFT”) or a TFT having a polycrystalline silicon film as an active layer (hereinafter referred to as “polycrystalline silicon TFT”) has conventionally been widely used.

In recent years, using an oxide semiconductor instead of amorphous silicon or polycrystalline silicon as a material for the active layer of a TFT has been proposed. Such a TFT is referred to as “oxide semiconductor TFT”. An oxide semiconductor is higher in mobility than amorphous silicon. For this reason, an oxide semiconductor TFT can operate at a higher speed than an amorphous silicon TFT. Further, using an oxide semiconductor TFT makes it possible to provide a higher-definition display panel than in a case where an amorphous silicon TFT is used. An active matrix substrate using an oxide semiconductor may be applied mainly to a small-to-medium-sized liquid crystal panel such as that for use in a smartphone.

Various modes of operation of an active matrix liquid crystal display device have been proposed and adopted depending on the intended use. Examples of the modes of operation include a TN (twisted nematic) mode, a VA (vertical alignment) mode, an IPS (in-plane-switching) mode, an FFS (fringe field switching) mode. Of these modes of operation, the TN mode and the VA mode are each a longitudinal electric field mode in which an electric field is applied to liquid crystal molecules by a pair of electrodes disposed with a liquid crystal layer sandwiched therebetween. The IPS mode and the FFS mode are each a transverse electric field mode in which one substrate is provided with a pair of electrodes and an electric field is applied to liquid crystal molecules in a direction (transverse direction) parallel with a board surface.

An FFS-mode active matrix substrate including an oxide semiconductor TFT is disclosed, for example, in Japanese Unexamined Patent Application Publication No. 2019-053105. Japanese Unexamined Patent Application Publication No. 2019-053105 proposes a structure in which a pixel electrode is disposed closer to a substrate than source and drain electrodes of the oxide semiconductor TFT and a common electrode is disposed on top of an interlayer insulating layer covering the oxide semiconductor TFT.

An increase in the number of processes of manufacturing an active matrix substrate undesirably invites an increase in manufacturing cost. For example, in the case of an active matrix substrate that is used in an FFS-mode liquid crystal display device, there tends to be increases in the number of manufacturing processes and the number of photomasks that are used, as there is a need for multilayer structures such as two transparent electrodes (namely a pixel electrode and a common electrode) disposed on top of each other with an insulating layer interposed therebetween, a semiconductor layer, a gate bus line, and a source bus line.

It is desirable to provide an active matrix substrate that includes an oxide semiconductor TFT and that makes it possible to reduce manufacturing costs by reducing the number of manufacturing processes.

### SUMMARY

According to an aspect of the disclosure, there is provided an active matrix substrate having a display region including a plurality of pixel regions. The active matrix substrate includes a substrate, a plurality of thin-film transistors, supported on the substrate and associated with the plurality of pixel regions, a plurality of pixel electrodes disposed in the plurality of pixel regions, and a first insulating layer located above the plurality of thin-film transistors and the plurality of pixel electrodes. Each of the pixel electrodes is formed from a transparent conducting material. Each of the thin-film transistors includes a gate electrode, a gate insulating layer covering the gate electrode, source and drain electrodes placed at a distance from each other on top of the gate insulating layer, and an oxide semiconductor layer. The oxide semiconductor layer includes a channel region that is in contact with the gate insulating layer between the source electrode and the drain electrode, a source contact region that is in contact with at least part of an upper surface of the source electrode, and a drain contact region that is in contact with at least part of an upper surface of the drain electrode. The source electrode has a stack structure including a source transparent conducting layer formed at a layer that is identical to that at which each of the pixel electrodes is formed and a source metal layer disposed on top of part of an upper surface of the source transparent conducting layer and formed from a metal material. The drain electrode includes a drain transparent conducting layer formed at a layer that is identical to that at which each of the pixel electrodes is formed. The drain transparent conducting layer is formed integrally with a corresponding one of the plurality of pixel electrodes.

According to an aspect of the disclosure, there is provided a method for manufacturing an active matrix substrate including a plurality of source bus lines, a plurality of gate bus lines, a plurality of thin-film transistors, and a plurality of pixel electrodes. The method includes (a) forming, on top of a substrate, gate electrodes of the plurality of thin-film transistors and the plurality of gate bus lines, (b) forming a gate insulating layer on top of the gate electrodes of the plurality of thin-film transistors and the plurality of gate bus lines, (c) forming a first transparent conducting film on top of the gate insulating layer and forming a source conducting film on top of the first transparent conducting film, (d) patterning the first transparent conducting film and the source conducting film by one photolithography process with a multi-tone mask and thereby forming the plurality of source bus lines, source and drain electrodes of the plurality of thin-film transistors, and the plurality of pixel electrodes, the plurality of source bus lines and the source electrodes having a stack structure including the first transparent conducting film and the source conducting film, the drain electrodes including at least the first transparent conducting film, the plurality of pixel electrodes including the first transparent conducting film but not including the source conducting film, and (e) after (d), forming and patterning an oxide semiconductor film and thereby forming a plurality of oxide semiconductor layers that are to serve as active layers of the plurality of thin-film transistors.

### BRIEF DESCRIPTION OF THE DRAWINGS

FIG. 1 is a diagram schematically showing an example of a planar structure of an active matrix substrate according to an embodiment;

FIG. 2A is an enlarged plan view illustrating one pixel region in the active matrix substrate;

FIG. 2B is a cross-sectional view taken along line IIB-IIB shown in FIG. 2A;

FIG. 3A is a plan view illustrating a terminal;

FIG. 3B is a cross-sectional view taken along line IIIB-IIIB shown in FIG. 3A;

FIG. 4A is a plan view illustrating a terminal;

FIG. 4B is a cross-sectional view taken along line IVB-IVB shown in FIG. 4A;

FIG. 5A is a process cross-sectional view showing a method for manufacturing an active matrix substrate;

FIG. 5B is a process cross-sectional view showing the method for manufacturing an active matrix substrate;

FIG. 5C is a process cross-sectional view showing the method for manufacturing an active matrix substrate;

FIG. 5D is a process cross-sectional view showing the method for manufacturing an active matrix substrate;

FIG. 5E is a process cross-sectional view showing the method for manufacturing an active matrix substrate;

FIG. 5F is a process cross-sectional view showing the method for manufacturing an active matrix substrate;

FIG. 5G is a process cross-sectional view showing the method for manufacturing an active matrix substrate;

FIG. 5H is a process cross-sectional view showing the method for manufacturing an active matrix substrate;

FIG. 5I is a process cross-sectional view showing the method for manufacturing an active matrix substrate;

FIG. 5J is a process cross-sectional view showing the method for manufacturing an active matrix substrate;

FIG. 6 is a diagram schematically showing a process for manufacturing an active matrix substrate;

FIG. 7A is an enlarged plan view illustrating one pixel region in an active matrix substrate according to Modification 1;

FIG. 7B is a cross-sectional view taken along line VIIB-VIIB shown in FIG. 7A;

FIG. 8A is a plan view illustrating a terminal according to Modification 1;

FIG. 8B is a cross-sectional view taken along line VIIIB-VIIIB shown in FIG. 8A;

FIG. 9 is a cross-sectional view showing part of an active matrix substrate according to Modification 2;

FIG. 10 is a cross-sectional view showing part of another active matrix substrate according to Modification 2;

FIG. 11A is an enlarged plan view illustrating one pixel region in an active matrix substrate according to Modification 3;

FIG. 11B is a cross-sectional view taken along line XIB-XIB shown in FIG. 11A; and

FIG. 12 is an enlarged plan view illustrating another active matrix substrate according to Modification 3.

### DESCRIPTION OF THE EMBODIMENTS

### Embodiment

An active matrix substrate according to an embodiment of the present disclosure is described below with reference to the drawings. A description is given here by taking, as an example, an active matrix substrate that is used in an FFS-mode liquid crystal display device. Note that the active matrix substrate according to the present embodiment encompasses a wide range of active matrix substrates that are used in liquid crystal display devices of other modes of operation, various display devices and electronics other than liquid crystal display devices, or other devices.

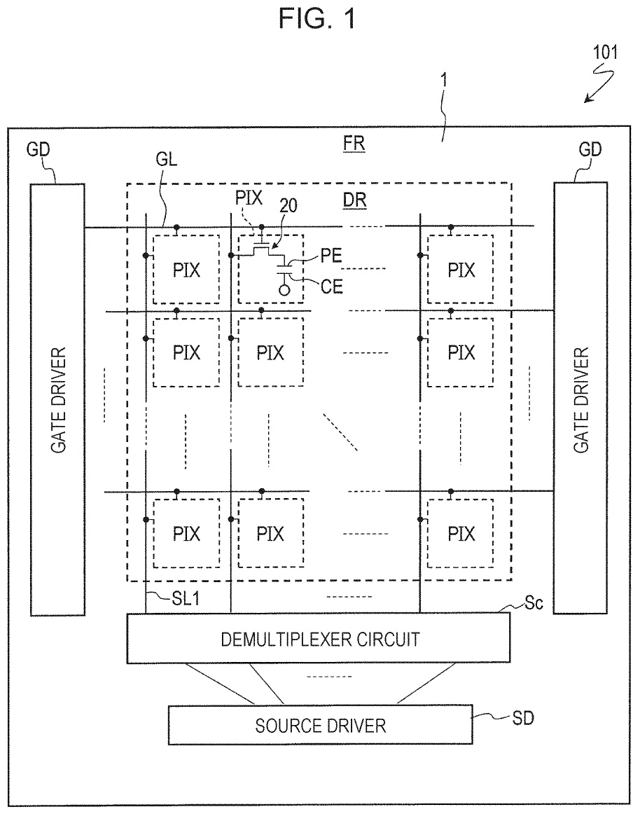

FIG. 1 is a plan view schematically showing an example of an active matrix substrate 101. The active matrix substrate 101 has a display region DR that contributes to display and a peripheral region (frame region) FR located outside the display region DR. The display region DR includes a plurality of pixel regions PIX arrayed in a row-wise direction and a column-wise direction in a matrix. The pixel regions PIX (sometimes simply called “pixels”) are regions corresponding to pixels of the display device. The non-display region FR is a region, located around the display region DR, that does not contribute to display.

The active matrix substrate 101 includes, in the display region DR, a plurality of source bus lines SL each extending in the column-wide direction and a plurality of gate bus lines GL each extending in the row-wise direction. The phrase “extending in the row-wise direction” needs only means extending substantially in the row-wise direction overall, and may encompass a portion extending in a direction intersecting the row-wise direction. Similarly, the phrase “extending in the column-wise direction” needs only means extending substantially in the column-wise direction overall, and may encompass a portion extending in a direction intersecting the column-wise direction. Each pixel region PIX is defined, for example, by gate bus lines GL and source bus lines SL.

The active matrix substrate 101 further includes, in the display region DR, a substrate 1, a plurality of pixel TFTs (hereinafter simply referred to as “TFTs”) 20 supported on the substrate 1, and a plurality of pixel electrodes PE. Each TFT 20 and each pixel electrode PE are provided in correspondence with one of the plurality of pixel regions PIX.

Each of the TFTs 20 is an oxide semiconductor TFT having an oxide semiconductor layer as active layer. Part (called “source contact region”) of the oxide semiconductor layer of the TFT 20 is electrically connected to one of the source bus lines SL. Part (called “drain contact region”) of the oxide semiconductor layer of the TFT 20 is electrically connected to a pixel electrode PE.

In a case where the active matrix substrate 101 is applied to a display device of a transverse electric field mode such as an FFS mode, the active matrix substrate 101 is provided with an electrode (common electrode) CE that is common to the plurality of pixel regions PIX.

In the non-display region FR, a peripheral circuit such as a gate drive GD that drives the gate bus lines GL is monolithically formed. Further, a demultiplexer circuit Sc that drives the source bus lines SL in a time-sharing manner may be formed. In the non-display region FR, a source driver SD may be mounted, for example, by COG (Chip on Glass). In the non-display region FR, wiring connections such as a plurality of gate terminals, a plurality of source terminals, and a plurality of source-gate wiring connections are disposed. The source-gate wiring connections are interconnections between a layer formed from the same conducting film as the source bus lines SL and a layer formed from the same conducting film as the gate bus lines GL.

Each gate bus line GL is connected to the gate drive GD via a corresponding gate terminal. Each source bus line SL is connected to the source drive SD via a corresponding source terminal.

### Structure of Pixel Region PIX of Active Matrix Substrate 101

A structure of a pixel region of the active matrix substrate 101 is more specifically described below with reference to the drawings.

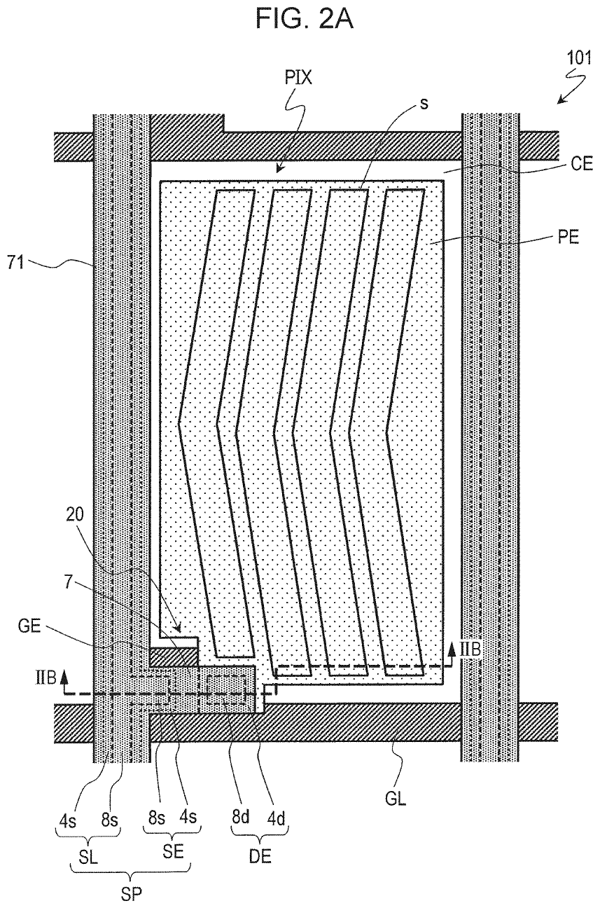

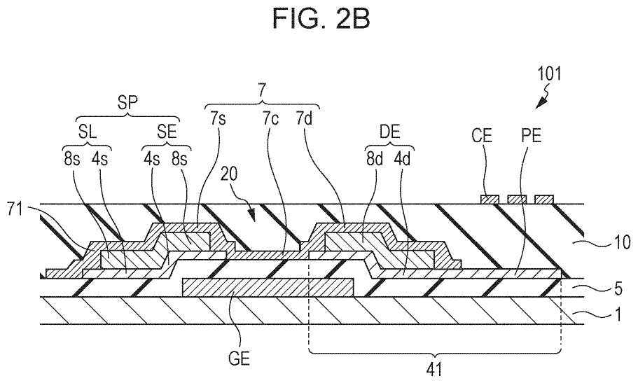

FIG. 2A is a plan view illustrating a pixel region PIX in the active matrix substrate 101. FIG. 2A shows one pixel region PIX, although the active matrix substrate 101 has a large number of pixel regions. FIG. 2B is a cross-sectional view taken along line IIB-IIB shown in FIG. 2A, and shows a cross-section of a TFT 20 in a channel length direction.

The active matrix substrate 101 includes a substrate 1 having a principal surface, a plurality of gate bus lines GL, supported on the principal surface of the substrate 1, that extend in the row-wise direction, and a plurality of source bus lines SL, supported on the principal surface of the substrate 1, that extend in the column-wise direction. The pixel region PIX is a region surrounded by two adjacent source bus lines SL and two adjacent gate bus lines GL.

Each pixel region PIX includes a TFT 20 supported on the substrate 1, a pixel electrode PE, and a common electrode CE. The pixel electrode PE and the common electrode CE are formed from a transparent conducting material.

The TFT 20 in each pixel region PIX is for example a bottom-gate TFT. Specifically, the TFT 20 includes a gate electrode GE disposed on top of the substrate 1, a gate insulating layer 5 covering the gate electrode GE, source and drain electrodes SE and DE disposed at a spacing from each other on top of the gate insulating layer 5, and an oxide semiconductor layer 7 disposed above the source electrode SE and the drain electrode DE. The TFT 20 has a structure (bottom-contact structure) in which the source electrode SE and the drain electrode DE are disposed in contact with a lower surface of the oxide semiconductor layer 7, which serves as an active layer.

When seen from a direction normal to the substrate 1, the oxide semiconductor layer 7 includes a channel region 7c, a source contact region 7s, and a drain contact region 7d. The source contact region 7s and the drain contact region 7d are located on both sides, respectively, of the channel region 7c. The channel region 7c is a region touching a portion of the gate insulating layer 5 exposed between the source electrode SE and the drain electrode DE and overlapping the gate electrode GE via the gate insulating layer 5. The source contact region 7s is a region, electrically connected to the source electrode SE, that overlaps the source electrode SE when seen from a direction normal to the substrate 1. The drain contact region 7d is a region, electrically connected to the drain electrode DE, that overlaps the drain electrode DE when seen from a direction normal to the substrate 1. In this example, the source contact region 7s of the oxide semiconductor layer 7 is in direct contact with at least part of an upper surface of the source electrode SE, and the drain contact region 7d is in direct contact with at least part of an upper surface of the drain electrode DE. The channel region 7c is a semiconductor region, and the source contact region 7s and the drain contact region 7d may be low-resistance regions (also called “conductor regions”) that are lower in specific resistance than the channel region 7c.

The gate electrode GE of the TFT 20 is connected to a corresponding gate bus line GL, and the source electrode SE is connected to a corresponding source bus line SL. The drain electrode DE is electrically connected to the pixel electrode PE.

In this example, the gate electrode GE of the TFT 20 and the gate bus lines GL are formed from the same conducting film (gate conducting film). A layer including those electrodes and wires formed from the gate conducting film is herein called “gate metal layer”. The gate electrode GE may be formed integrally with a corresponding gate bus line GL. The gate electrode GE may be part of the gate bus line GL or, as illustrated, may be a projection projecting in the column-wise direction from the gate bus line GL when seen from a direction normal to the substrate 1. The gate insulating layer 5 is disposed on top of the gate metal layer. The gate insulating layer 5 is formed so as to cover the gate metal layer.

The pixel electrode PE is disposed on top of the gate insulating layer 5. The pixel electrode PE is a transparent electrode formed from a first transparent conducting film. The pixel electrode PE does not include a non-translucent metal film (e.g. the after-mentioned source conducting film). In the illustrated example, the pixel electrode PE is in direct contact with the upper surface of the gate insulating layer 5.

In the present embodiment, the source electrode SE of the TFT 20 and the source bus lines SL have a stack structure including a source transparent conducting layer 4s and a source metal layer 8s disposed on an upper surface of the source transparent conducting layer 4s. The source transparent conducting layer 4s is formed at the same layer as the pixel electrode PE (i.e. formed from the same first transparent conducting film as the pixel electrode PE). When it is said herein that two constituent elements such as electrodes, wires, or oxide layers are “formed at the same layer”, it means that these two constituent elements are formed from the same film. The source metal layer 8s includes a metal material. The source metal layer 8s is formed from a source conducting film (e.g. a metal film such as a Cu film). A layer including those electrodes and wires formed from the source conducting film is herein sometimes referred to as “source metal layer”.

The source electrode SE may be formed integrally with a corresponding source bus line SL. The source electrode SE may be part of the source bus line SL. Alternatively, the source electrode SE may be a projection projecting in the row-wise direction from the source bus line SL when seen from a direction normal to the substrate 1. A continuous conductive portion SP including a source bus line SL and a source electrode SE formed integrally with the source bus line SL (typically, the source electrodes SE of a plurality of pixel TFTs associated with the source bus line SL) is herein called “source portion”. In the source portion SP, the source metal layer 8s is disposed so as to cover only part of an upper surface of the source transparent conducting layer 4s. When seen from a direction normal to the substrate 1, the source metal layer 8s is located inside a peripheral edge of the source transparent conducting layer 4s. In other words, the source metal layer 8s has end faces (side surfaces) located on top of the upper surface of the source transparent conducting layer 4s.

The drain electrode DE of the TFT 20 has a stack structure including a drain transparent conducting layer 4d formed at the same layer as the pixel electrode PE (i.e. formed from the first transparent conducting film) and a drain metal layer 8d formed at the same layer as the source metal layer 8s (i.e. formed from the source conducting film). In this example, the drain transparent conducting layer 4d of the drain electrode DE is formed integrally with the pixel electrode PE. That is, the pixel electrode PE is connected to the drain transparent conducting layer 4d of the drain electrode DE. A continuous conductive portion 41 including a drain transparent conducting layer 4d and a pixel electrode PE in each pixel region PIX is herein called “transparent electrode section”. Such a transparent electrode section 41 is provided for each pixel region. The transparent electrode sections 41 of two adjacent pixel regions are placed at a distance from each other and electrically isolated from each other. The drain metal layer 8d is disposed so as to cover only part of an upper surface of the transparent electrode section 41. When seen from a direction normal to the substrate 1, the drain metal layer 8d is located inside a peripheral edge of the transparent electrode section 41.

As will be described later, the source bus lines SL, the pixel electrode PE, the source and drain electrodes SE and DE of the TFT 20 may be formed by patterning a film stack of the first transparent conducting film and the source conducting film by one photolithography process with a multi-tone mask (here, a half-tone mask). The method of formation will be described later.

As illustrated, the oxide semiconductor layer 7 may cover the entire upper and side surfaces of the source metal layer 8s in the source electrode SE and the entire upper and side surfaces of the drain metal layer 8d in the drain electrode DE. This makes it possible to restrain the source metal layer 8s and the drain metal layer 8d from being damaged or parts of these metal layers 8s and 8d from being removed with an etchant in an etching process by which the oxide semiconductor layer 7 is formed.

It is preferable that the oxide semiconductor layer 7 not cover a portion of the transparent electrode section 41 that functions as the pixel electrode PE. For example, the pixel electrode PE may be a portion of the transparent electrode section 41 exposed from both the drain metal layer 8d and the oxide semiconductor layer 7.

The active matrix substrate 101 may further include a plurality of wire covering layers 71 formed at the same layer as the oxide semiconductor layer 7 (i.e. formed from the same oxide semiconductor film as the oxide semiconductor layer 7). Each wire covering layer 71 is disposed on top of a corresponding source bus line SL, covers the source bus line SL, and extends in the column-wise direction. Each wire covering layer 71 and corresponding oxide semiconductor layers 7 (typically, the oxide semiconductor layers of a plurality of pixel TFTs associated with the source bus line SL) may be formed integrally from the same oxide semiconductor film. The wire covering layer 71 may be a low-resistance region that is lower in specific resistance than the channel region 7c.

In the illustrated example, the oxide semiconductor layer 7 and the wire covering layer 71 cover upper and side surfaces of the source portion SP including the source electrode SE and the source bus line SL and are also in contact with a region on the upper surface of the gate insulating layer 5 close to the side surfaces of the source portion SP. Since the side surfaces of the source portion SP are in a stepped or tapered shape including the side surfaces of the source metal layers 8s and side surfaces of the source transparent conducting layer 4s disposed on a side of the source metal layer 8s beside the substrate 1 and located further outward than the source metal layer 8s, the oxide semiconductor layer 7 and the wire covering layer 71 may have satisfactory coverage. Note that the oxide semiconductor layer 7 and the wire covering layer 71 need only cover at least the entire upper and side surfaces of the source metal layer 8s.

Disposed above the oxide semiconductor layer 7 and the wire covering layer 71 is a first insulating layer 10. The oxide semiconductor layer 7 and the wire covering layer 71 may have their upper surfaces in contact with the first insulating layer 10. The first insulating layer 10 is provided so as to cover the TFT 20, the source bus line SL, the gate bus line GL, and the wire covering layer 71. The first insulating layer 10 is for example an inorganic insulating layer (passivation film). The first insulating layer 10 does not need to include an organic insulating film.

The common electrode CE is disposed so as to partially overlap the pixel electrode PE via the first insulating layer 10. In each pixel region, the common electrode CE has at least one opening s or a notch. The common electrode CE does not need to be separated for each pixel region. The common electrode CE may be disposed all over a display region excluding a region located on top of the TFT 20.

Thus, in the present embodiment, the pixel electrode PE and the source and drain electrodes SE and DE of the TFT 20 are located at a higher layer than the gate insulating layer 5 and at a lower layer than the oxide semiconductor layer 7. The source electrode SE and the drain electrode DE each have a stack stricture whose lower layer is the transparent conducting layers 4s and 4d formed at the same layer as the pixel electrode PE (i.e. formed from the first transparent conducting film) and whose upper layer is the metal layers 8s and 8d formed from the source conducting film. Such a configuration makes it possible to form the first transparent conducting film and the source conducting film in this order on top of the gate insulating layer 5 and form the pixel electrode PE and the source and drain electrodes SE and DE of the TFT 20 from those conducting films by one photolithography process with a multi-tone mask.

For example, in a configuration, such as that of Japanese Unexamined Patent Application Publication No. 2019-053105, in which an oxide semiconductor layer and a pixel electrode are disposed on top of a gate insulating layer and source and drain electrodes are provided at a higher layer than that, etching of an oxide semiconductor film by an etchant that is used in patterning of a transparent conducting film (ITO film) that is to serve as the pixel electrode is avoided by forming the oxide semiconductor film after having formed the pixel electrode by patterning of the ITO film. Doing so makes it necessary to pattern the oxide semiconductor film and a source conducting film all with separate photomasks, and at least three different photomasks are used in the formation of the oxide semiconductor layer, the pixel electrode, the source electrode, and the drain electrode.

On the other hand, the present embodiment makes it possible to, as mentioned above, pattern the source and drain electrodes and the pixel electrode with the same photomask (multi-tone mask) and then pattern the oxide semiconductor film with another photomask. Accordingly, the oxide semiconductor layer, the pixel electrode, the source electrode, and the drain electrode can be formed with two photomasks. This makes it possible to make the number of photomasks (or the number of photolithography processes) smaller than does the configuration of Japanese Unexamined Patent Application Publication No. 2019-053105.

Further, in the active matrix substrate 101 according to the present embodiment, the source metal layers 8s and the drain metal layer 8d have their upper and side surfaces covered with the oxide semiconductor layer 7 or a covering layer (here, the wire covering layer 71) formed at the same layer as the oxide semiconductor layer 7. In this example, the oxide semiconductor layer 7 and the wire covering layer 71 are formed so as to cover the source line SL and the entire surfaces (upper and side surfaces) the metal layers 8s and 8d of the source and drain electrodes SE and DE. This restrains the surfaces of the metal layers 8s and 8d from being damaged or etched by an etchant for the oxide semiconductor film. This makes it possible to increase the degree of freedom of selection of a material for the metal layers 8s and 8d and an etchant for the oxide semiconductor film.

### Terminal

In the non-display region of the active matrix substrate 101 according to the present embodiment, a plurality of terminals are disposed. These terminals may be terminals T1 constituted by the source metal layer or terminals T2 constituted by the gate metal layer.

Alternatively, these terminals may include both terminals T1 and terminal T2.

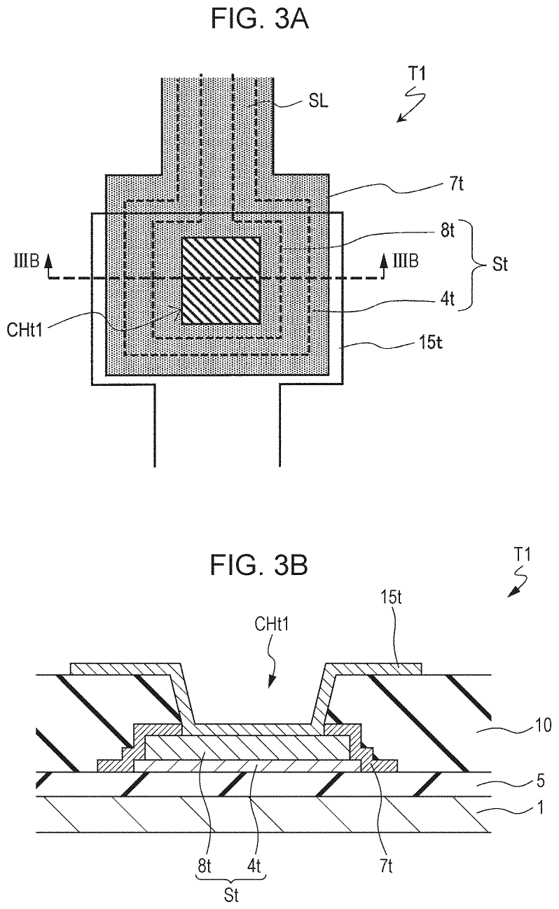

FIG. 3A is a plan view of a terminal T1, and FIG. 3B is a cross-sectional view taken along line IIIB-IIIB shown in FIG. 3A.

The terminal T1 has a source connection St disposed on top of the gate insulating layer 5, a connection covering layer 7t covering part of the source connection St, an extension of the first insulating layer 10 provided on top of the source connection St and the connection covering layer 7t, and an upper connection 15t. The connection covering layer 7t and the first insulating layer 10 have formed therein a contact hole CHt1 through which part of the source connection St is exposed. The upper connection 15t is disposed on top of the first insulating layer 10 and in the contact hole CHt1, and is electrically connected to the source connection St in the contact hole CHt1.

The source connection St has a stack structure including a connection transparent conducting layer 4t formed from the first transparent conducting film and a connection metal layer 8t formed from the source conducting film (in the source metal layer). The connection metal layer 8t is disposed on top of part of an upper surface of the connection transparent conducting layer 4t. The source connection St may for example be an end of the source bus line SL or an end of another wire (e.g. a wire electrically connected to the gate bus line GL). The connection covering layer 7t is formed from the same oxide semiconductor film as the oxide semiconductor layer 7, and covers part of an upper surface and side surfaces of the source connection St. Since the side surfaces of the source connection St are in a stepped shape including the side surfaces of the connection metal layer 8t and side surfaces of the connection transparent conducting layer 4t disposed on a side of the connection metal layer 8t beside the substrate 1 and located further outward than the connection metal layer 8t, the connection covering layer 7t may have satisfactory coverage. Providing the connection covering layer 7t restrains the connection metal layer 8t from being damaged or etched by an etchant for forming the connection covering layer 7t. The upper connection 15t is formed, for example, from the same transparent conducting film as the common electrode CE.

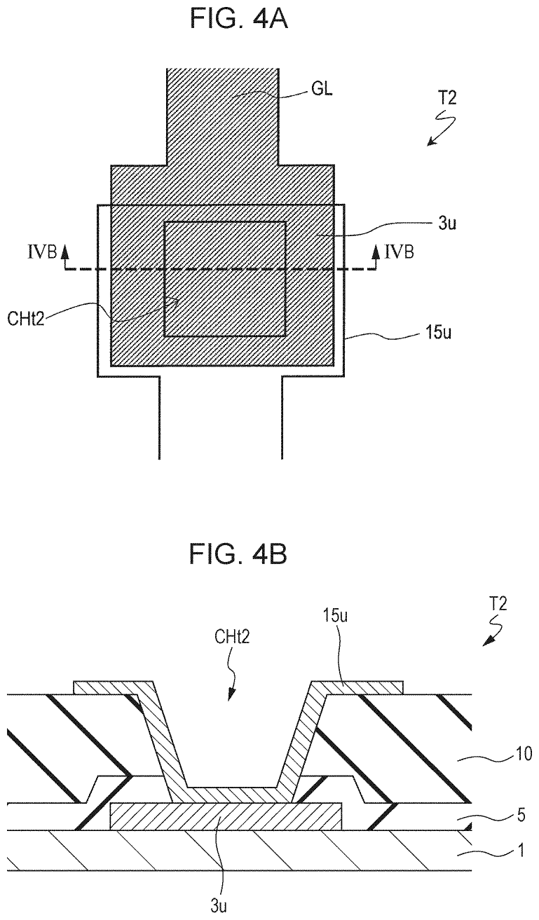

FIG. 4A is a plan view of a terminal T2, and FIG. 4B is a cross-sectional view taken along line IVB-IVB shown in FIG. 4A.

The terminal T2 has a gate connection 3u disposed on top of the substrate 1, extensions of the gate insulating layer 5 and the first insulating layer 10 provided on top of the gate connection 3u, and an upper connection 15u. The gate connection 3u is formed from the gate conducting film (in the gate metal layer). The gate connection 3u may for example be an end of the gate bus line GL or an end of another wire (e.g. a wire electrically connected to the source bus line SL). The upper connection 15u may be formed from the same transparent conducting film as the common electrode CE. The first insulating layer 10 and the gate insulating layer 5 have formed therein a contact hole CHt2 through which part of the gate connection 3u is exposed. The upper connection 15u is disposed on top of the first insulating layer 10 and in the contact hole CHt2, and is electrically connected to the gate connection 3u in the contact hole CHt2.

### Method for Manufacturing Active Matrix Substrate 101

In the following, a method for manufacturing an active matrix substrate 101 according to the present embodiment is described with reference to the drawings. A method for manufacturing an active matrix substrate 101 with five photomasks is described here.

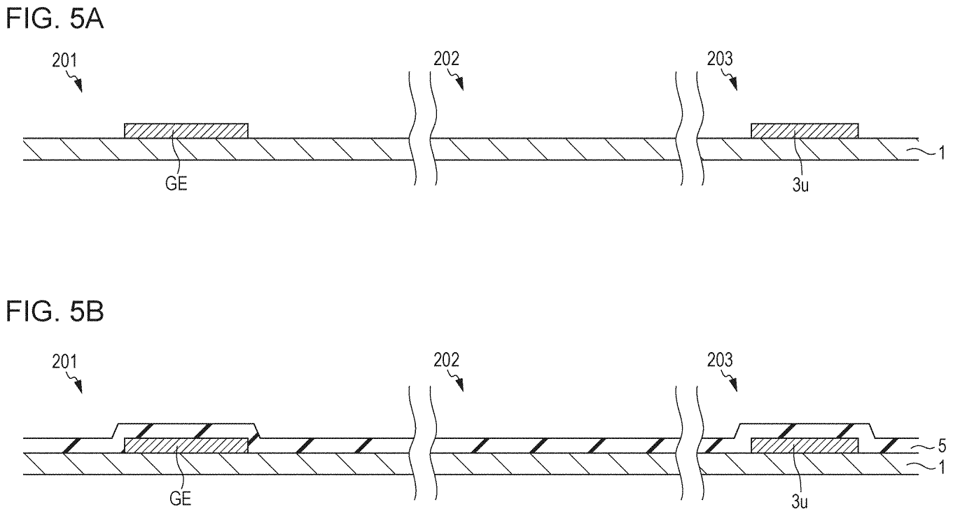

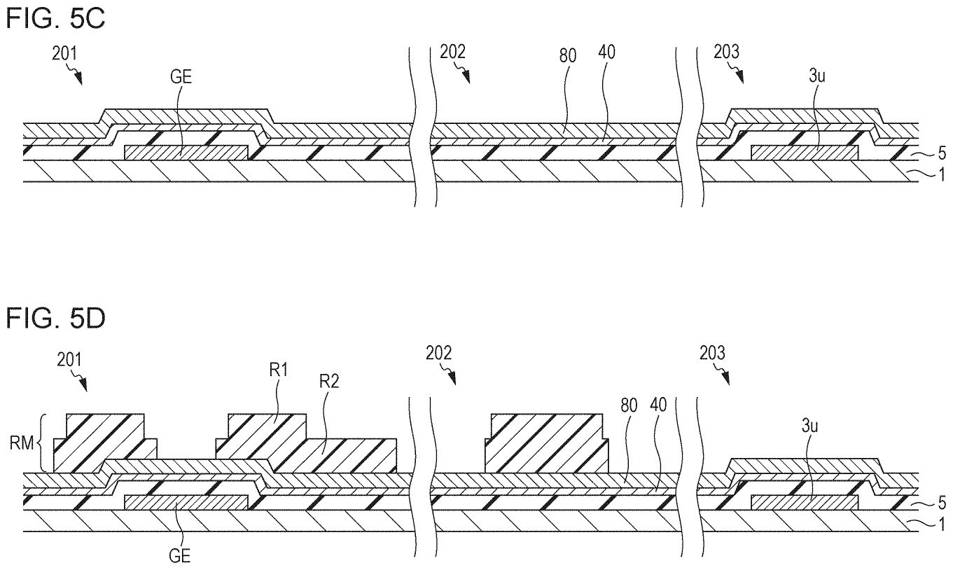

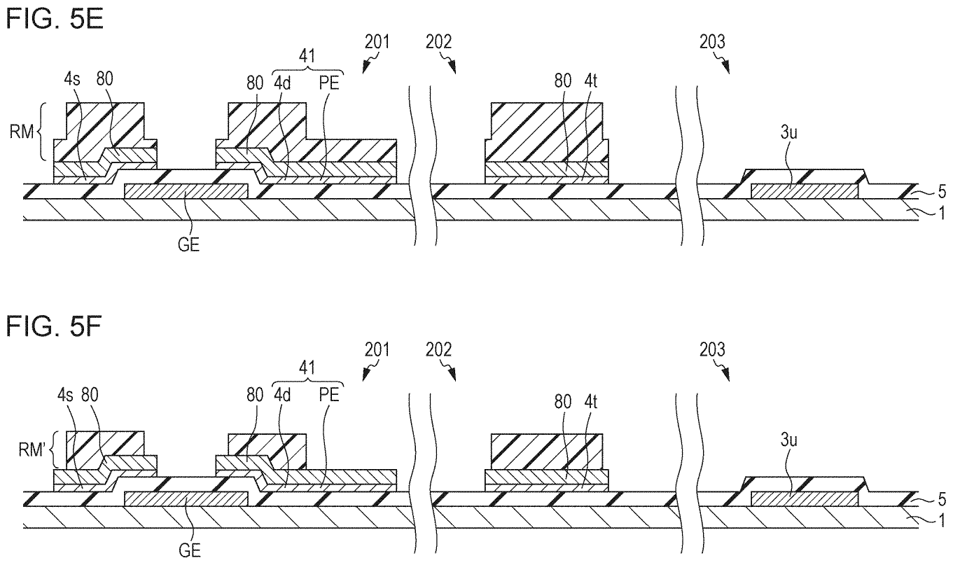

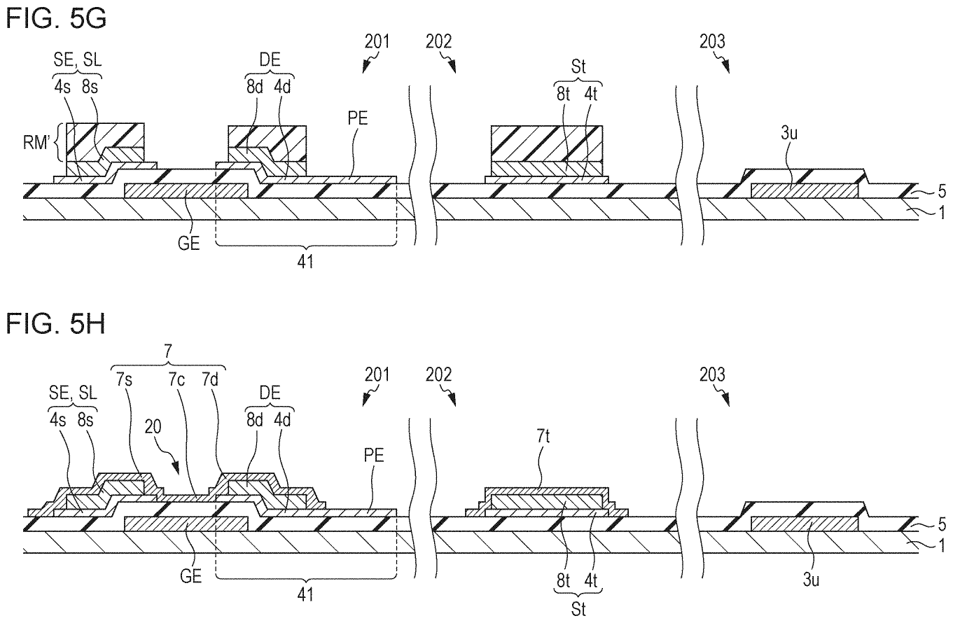

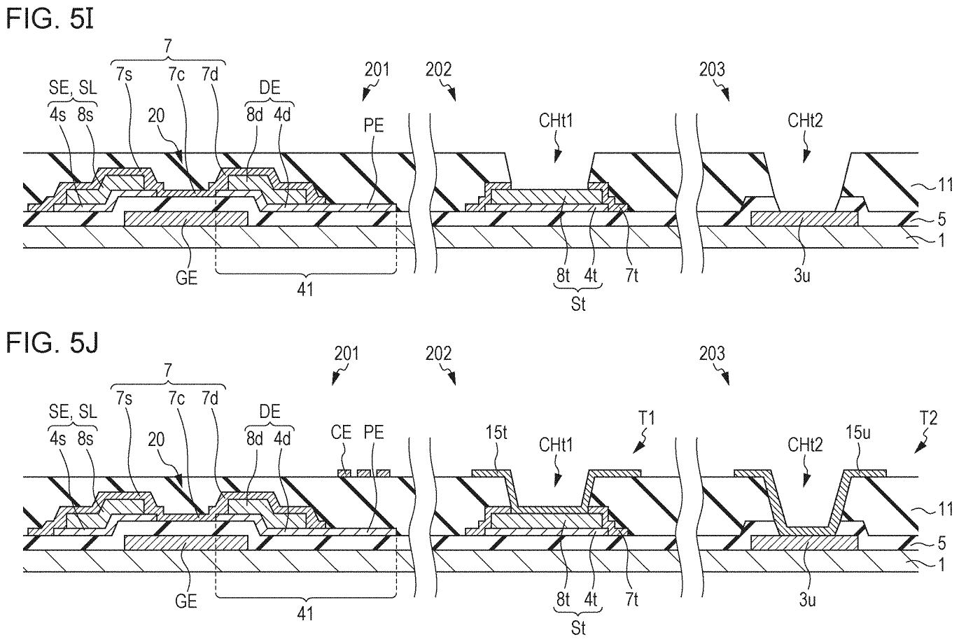

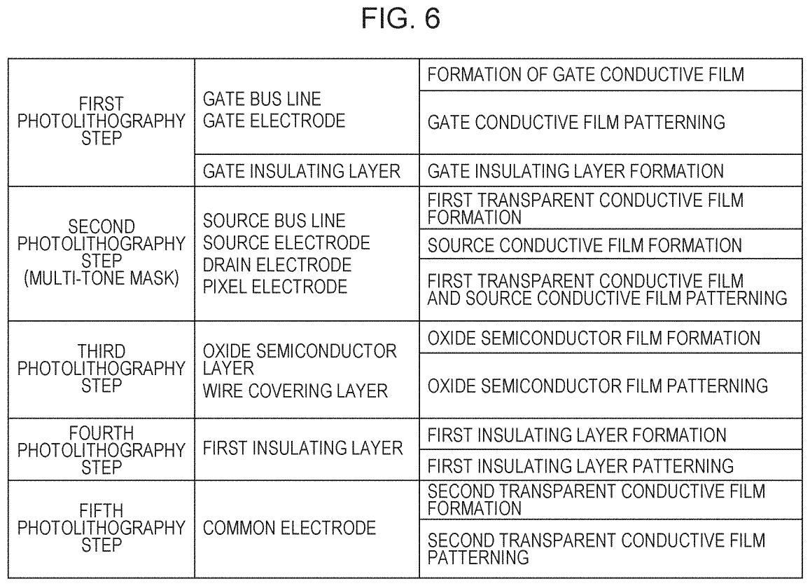

FIGS. 5A to 5J are process cross-sectional views for explaining an example of a method for manufacturing an active matrix substrate 101 and shows a TFT formation region 201 where a TFT is formed and terminal formation regions 202 and 203 where terminals T1 and T2 are formed. Although each figure shows both the terminal formation regions 202 and 203, the active matrix substrate 101 needs only have at least either of the terminal formation regions 202 and 203 (at least either of the terminals T1 and T2). FIG. 6 is a diagram schematically showing a process for manufacturing an active matrix substrate 101.

First, as shown in FIG. 5A, a gate conducting film (thickness: for example, greater than or equal to 50 nm and less than or equal to 650 nm) is formed on top of a substrate 1 and then patterned by a publicly-known photolithography process (first photolithography process). As a result of this, a gate metal layer including a gate electrode GE, a gate connection 3u, and a gate bus line GL is formed.

As the substrate 1, a transparent insulating substrate can be used. In this example, a glass substrate is used.

Appropriately usable examples of materials for the gate conducting film include, but are not limited to, films containing metals such as aluminum (Al), tungsten (W), molybdenum (Mo), tantalum (Ta), chromium (Cr), titanium (Ti), and copper (Cu) or alloys thereof. Alternatively, a film stack of these films may be used. In this example, as the gate conducting film, a Cu film (thickness: for example, 500 nm) is used. The Cu film is patterned, for example, by wet etching.

Next, as shown in FIG. 5B, a gate insulating layer 5 (thickness: for example, greater than or equal to 200 nm and less than or equal to 600 nm) is formed so as to cover the gate metal layer.

The gate insulating layer 5 is formed, for example, by a CVD method. Appropriately usable examples of the gate insulating layer 5 include a silicon oxide (SiOx) layer, a silicon nitride (SiNx) layer, a silicon oxynitride (SiOxNy; x>y) layer, and a silicon nitroxide (SiNxOy; x>y) layer. The gate insulating layer 5 may be a single layer or may have a stack structure. For example, a layer such as a silicon nitride (SiNx) layer or a silicon nitroxide is formed beside the substrate (as a lower layer) in order to prevent the spread of impurities from the substrate 1, a layer such as a silicon oxide (SiO₂) layer or a silicon oxynitride layer may be formed at a higher layer (as an upper layer) in order to secure insulating properties. In this example, as the gate insulating layer 5, a film stack whose lower layer is a silicon nitride (SiNx) layer (thickness: 50 to 600 nm) and whose upper layer is a silicon oxide (SiO₂) layer (thickness: 50 to 600 nm) may be formed.

After this, as shown in FIG. 5C, a first transparent conducting film 40 (thickness: for example, greater than or equal to 20 nm and less than or equal to 300 nm) and a source conducting film 80 (thickness: for example, greater than or equal to 50 nm and less than or equal to 600 nm) are formed in this order on top of the gate insulating layer 5.

Usable examples of the first transparent conducting film 40 include metal oxide films such as an indium-tin-oxide (ITO) film, an indium-zinc-oxide film (IZO), and a zinc oxide (ZnO) film. In this example, as the first transparent conducting film 40, an ITO film (thickness: 100 nm) is formed, for example, by a sputtering method.

Appropriately usable examples of materials for the source conducting film 80 include, but are not limited to, films containing metals such as aluminum (Al), tungsten (W), molybdenum (Mo), tantalum (Ta), chromium (Cr), titanium (Ti), and copper (Cu) or alloys thereof. Alternatively, a film stack of these films may be used. In this example, as the source conducting film 80, a Cu film (thickness: for example, 500 nm) is formed, for example, by a sputtering method. Alternatively, a film stack whose lower layer is a Ti film (thickness: 15 to 70 nm) and whose upper layer is a Cu film (thickness: 50 to 550 nm) may be formed.

Then, a photoresist film is formed on top of the source conducting film 80, exposed with a multi-tone mask, and then developed (second photolithography process). As a result of this, as shown in FIG. 5D, a resist layer RM including a first region R1 and a second region R2 that is thinner than the first region R1 is formed on top of the gate insulating layer 5.

Usable examples of the multi-tone mask include a gray-tone mask and a half-tone mask. The gray-tone mask has formed there in a slit that is lower than the resolution of a photolithography machine, and intermediate exposure is achieved by this slit blocking a portion of light. Meanwhile, the half-tone mask achieves intermediate exposure by using a semi-transmissive film.

Then, as shown in FIG. 5E, the source conducting film 80 and the first transparent conducting film 40 are etched with the resist layer RM as a mask. As a result of this, a source transparent conducting layer 4s and a transparent electrode section 41 including a drain transparent conducting layer 4d and a pixel electrode PE are formed from the first transparent conducting film 40 in the TFT formation region 201, and a connection transparent conducting layer 4t is formed from the first transparent conducting film 40 in the terminal formation region 202. The source conducting film 80 is patterned into the same pattern as the transparent electrode section 41 and the connection transparent conducting layer 4t.

In a case where a Cu film is used as the source conducting film 80, the Cu film and the first transparent conducting film (e.g. an ITO film) 40 may be etched at the same time. Meanwhile, in a case where a film stack whose lower layer is a Ti film and whose upper layer is a Cu layer is used as the source conducting film 80, the Cu film, the Ti film, and the first transparent conducting film 40 may be etched en bloc with a fluorine-containing etchant. Alternatively, the Cu film may be etched with a fluorine-free etchant, and then the Ti film may be dry-etched; furthermore, the first transparent conducting film 40 may be etched with an oxalic acid etchant.

After this, as shown in FIG. 5F, the second region R2 is removed by reducing the thickness of the resist layer RM by performing an ashing process on the resist layer RM. In this way, a resist layer RM′ is obtained.

Next, as shown in FIG. 5G, a portion of the source conducting film 80 exposed from the resist layer RM′ is removed by etching with the resist layer RM′ subjected to the ashing process. An etching method and an etchant for the source conducting film may be similar to the method and the etchant illustrated with reference to FIG. 5E. As a result of this, a source metal layer 8s and a drain metal layer 8d are obtained from the source conducting film 80 in the TFT formation region 201, and a connection metal layer 8t is obtained from the source conducting film 80 in the terminal formation region 202. When seen from a direction normal to the substrate 1, the source metal layer 8s is located inside a peripheral edge of the transparent electrode section 41, and the connection metal layer 8t is located inside the connection transparent conducting layer 4t.

In this way, from the first transparent conducting film 40 and the source conducting film 80, a source electrode SE and a source bus line SL both including the source transparent conducting layer 4s and the source metal layer 8s, a drain electrode DE including the drain transparent conducting layer 4d and the drain metal layer 8d, a pixel electrode PE including the first transparent conducting film 40 but not including the source conducting film 80, and a source connection St including the connection transparent conducting layer 4t and the connection metal layer 8t are formed. When seen from a direction normal to the substrate 1, sides surfaces of the source transparent conducting layer 4s and the drain transparent conducting layer 4d are located further outward than side surfaces of the source metal layer 8s and the drain metal layer 8d.

After this, an oxide semiconductor film (thickness: for example, greater than or equal to 15 nm and less than or equal to 200 nm) is formed so as to cover the source electrode SE, the source bus line SL, the drain electrode DE, the pixel electrode PE, and the source connection St. Next, the oxide semiconductor film is patterned by a publicly-known photolithography process (third photolithography process). As a result of this, as shown in FIG. 5H, an oxide semiconductor layer 7, a wire covering layer 71, and a connection covering layer 7t are obtained. In this way, a TFT 20 is formed in the TFT formation region 201.

The oxide semiconductor film may be formed by a sputtering method with a sputtering target having a desired composition. In this example, as the oxide semiconductor film, an In—Ga—Zn—O oxide semiconductor film (thickness: 50 nm) containing In, Ga, and Zn is formed. The oxide semiconductor film is not limited to this material. The material, composition ratio, structure, or other features of the oxide semiconductor film will be described later.

The oxide semiconductor film may be patterned, for example, by wet etching with a PAN (phosphoric acid-acetic acid-nitric acid) etchant. Alternatively, another etchant such as an oxalic acid etchant may be used. Using a PAN etchant removes the source conducting film (Cu film) too; however, in the present embodiment, the Cu film is not exposed to the etchant, as a portion of the oxide semiconductor film covering the Cu film is left without being removed. This makes it possible to pattern the oxide semiconductor film while maintaining the shape of the source metal layer (i.e. the shapes of the metal layers 8s and 8d).

Note that in a case where the metal layers 8s and 8d include metal films such as Cu films, Al films, or Mo films and a PAN etchant is used for etching of the oxide semiconductor film, exposure of parts of the metal films from the oxide semiconductor film to the PAN etchant may cause exposed portions of the metal films to be etched by eluating to the PAN etchant. Further, even in a case where metal films having resistance to an etchant for the oxide semiconductor film are used, the etchant may cause damage to the surfaces of the metal layers 8s and 8d. On the other hand, in the illustrated example, the active matrix substrate 101 is configured such that the oxide semiconductor film is patterned so as to cover the entire exposed surfaces of the source metal layer (here, the entire upper and side surfaces of the source metal layer 8s, the entire upper and side surfaces of the drain metal layer 8d, and the entire upper and side surfaces of the connection metal layer 8t). This restrains the surfaces of these metal layers 8s, 8d, and 8t from being damaged or etched by an etchant for the oxide semiconductor film.

The oxide semiconductor film may be made lower in resistance by touching a conducting film such as the source conducting film or the first transparent conducting film. Accordingly, the source contact region 7s, the drain contact region 7d, and the connection covering layer 7t may include low-resistance regions that are lower in specific resistance than the channel region 7c. The low-resistance regions may be conductor regions (for example, with a sheet resistance lower than or equal to 200 Ω/□.

Then, as shown in FIG. 5I, a first insulating layer 10 covering the TFT 20, the pixel electrode PE, and the connection covering layer 7t is formed, and the first insulating layer 10 is etched by a publicly-known photolithography process (fourth photolithography process). In this example, dry etching may cause part of the connection covering layer 7t to be exposed to the first insulating layer 10 in the terminal formation region 202. Further, a contact hole CHt2 through which part of the gate connection 3u is exposed is formed in the first insulating layer 10 and the gate insulating layer 5 in the terminal formation region 203. Next, a portion of the connection covering layer 7t exposed from the first insulating layer 10 is removed, for example, with an oxalic acid etchant, whereby a contact hole CHt1 through which part of the connection metal layer 8t is exposed is obtained.

Appropriately usable examples of the first insulating layer 10 include a silicon oxide (SiOx) layer, a silicon nitride (SiNx) layer, a silicon oxynitride (SiOxNy; x>y) layer, and a silicon nitroxide (SiNxOy; x>y) layer. The first insulating layer 10 may be a single layer or may have a stack structure. In this example, as the first insulating layer 10, a silicon oxide (SiO₂) layer (thickness: 100 nm) is formed. Alternatively, the first insulating layer 10 may have a film stack whose lower layer is a silicon oxide (SiO₂) layer and whose upper layer is a silicon nitride (SiNx) layer. A stack structure including a SiNx layer makes it possible to increase an auxiliary capacitance (transparent auxiliary capacitance) formed by the pixel electrode PE and the common electrode CE.

It is preferable that the first insulating layer 10 have, for example, a thickness greater than or equal to 100 nm and less than or equal to 600 nm. A thickness greater than or equal to 100 nm, preferably greater than or equal to 300 nm, makes it possible to secure insulating properties between the source metal layer and the common electrode CE. A thickness less than or equal to 600 nm makes it possible to increase an auxiliary capacitance (transparent auxiliary capacitance) formed by the pixel electrode PE and the common electrode CE. From the point of view of the securement of a transparent auxiliary capacitance and the miniaturization and manufacturing cost of the active matrix substrate 101, it is preferable that the first insulating layer 10 not include a planarizing layer such as an organic insulating layer.

After this, a second transparent conducting film is formed on top of the first insulating layer 10 and in the contact holes CHt1 and CHt2 and patterned by a publicly-known photolithography process (fifth photolithography process). The second transparent conducting film may be made of the same material as the first transparent conducting film. In this example, as the second transparent conducting film, an ITO film (thickness: 100 nm) is used. As a result of this, as shown in FIG. 5J, the common electrode CE is formed in the TFT formation region 201. Further, upper connections 15t and 15u are formed in the terminal formation regions 202 and 203, respectively, whereby terminals T1 and T2 are obtained. In this way, the active matrix substrate 101 is manufactured.

### Modifications

The following describes active matrix substrates according to modifications of the present embodiment. In the drawings of each modification, constituent elements that are similar to those of FIGS. 2A to 4B are given the same reference signs. Further, in a description of each modification, points of difference from FIGS. 2A to 4B are mainly described, and overlapping contents may be omitted.

### Modification 1

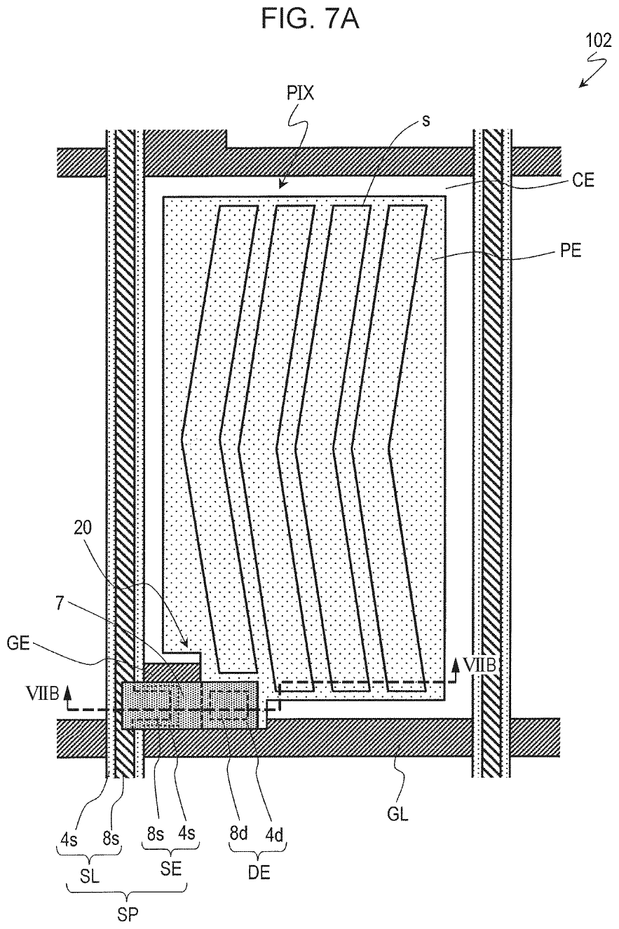

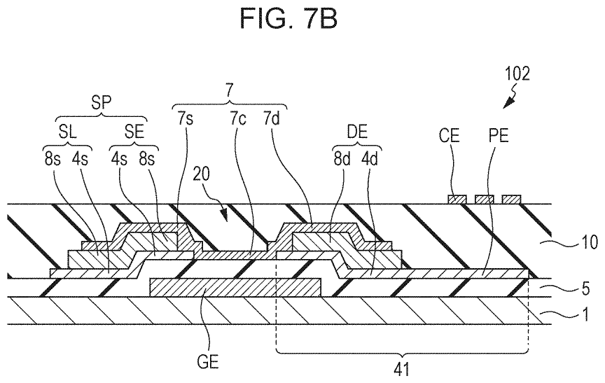

FIG. 7A is a plan view showing part of an active matrix substrate 102 according to Modification 1, and FIG. 7B is a cross-sectional view taken along line VIIB-VIIB shown in FIG. 7A.

The active matrix substrate 102 according to Modification 1 differs from the active matrix substrate 101 in that at least parts of those electrodes and wires in the source metal layer are exposed from the oxide semiconductor film.

In the active matrix substrate 102, at least part of the source metal layer 8s of the source portion SP is exposed from the oxide semiconductor layer 7, and at least part of the drain metal layer 8d of the drain electrode DE is exposed from the oxide semiconductor layer 7. In a cross-section taken along a channel length direction, a source side end face of the oxide semiconductor layer 7 is located on the upper surface of the source metal layer 8s, and a drain side end face of the oxide semiconductor layer 7 is located on top of the upper surface of the drain metal layer 8d. Portions of the upper and side surfaces of these metal layers 8s and 8d exposed from the oxide semiconductor layer 7 may be in contact with the first insulating layer 10. In the present modification, the area of the oxide semiconductor layer 7 can be reduced, as the oxide semiconductor layer 7 does not need to cover an end face of the source portion SP. This can result in a reduction in size of the TFT 20, thus making it to achieve finer resolution.

Further, in the active matrix substrate 102, the source metal layer 8s and the source transparent conducting layer 4s in the source bus line SL are not covered with the oxide semiconductor film. That is, the wire covering layer 71 (FIG. 2A) is not formed on top of the source bus line SL. As a result of this, the width of a region where the source bus line SL is formed can be made smaller than in a case where the wire covering layer 71 is formed. This makes it possible to increase a pixel aperture ratio or achieve finer resolution.

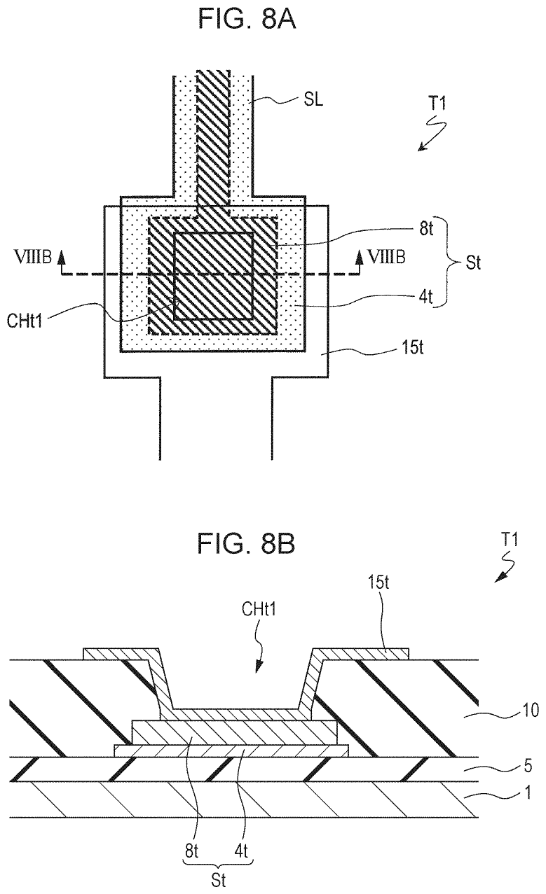

FIG. 8B is a cross-sectional view showing a terminal T1 according to Modification 1. In the present modification, the connection metal layer 8t of the terminal T1 is not covered with the oxide semiconductor film. That is, the connection covering layer 7t (FIG. 3A) is not formed on top of the connection metal layer 8t. Note that as in the case of the terminal T1 of the active matrix substrate 101, the connection covering layer 7t may be formed at the same layer as the oxide semiconductor layer 7. The structure of the terminal T2 is not illustrated, as it is similar to that of the active matrix substrate 101.

The active matrix substrate 102 may be manufactured by a process that is similar to that by which the active matrix substrate 101 is manufactured. Note, however, that in the process of patterning the oxide semiconductor film, the oxide semiconductor film is etched so that the source metal layer 8s, the drain metal layer 8d, and the connection metal layer 8t are each partially exposed. For this reason, it is preferable to select an etchant that is capable of selectively etching only the oxide semiconductor film while hardly etching these metal films 8s, 8d, and 8t. A usable example of such an etchant is an oxalic acid etchant.

### Modification 2

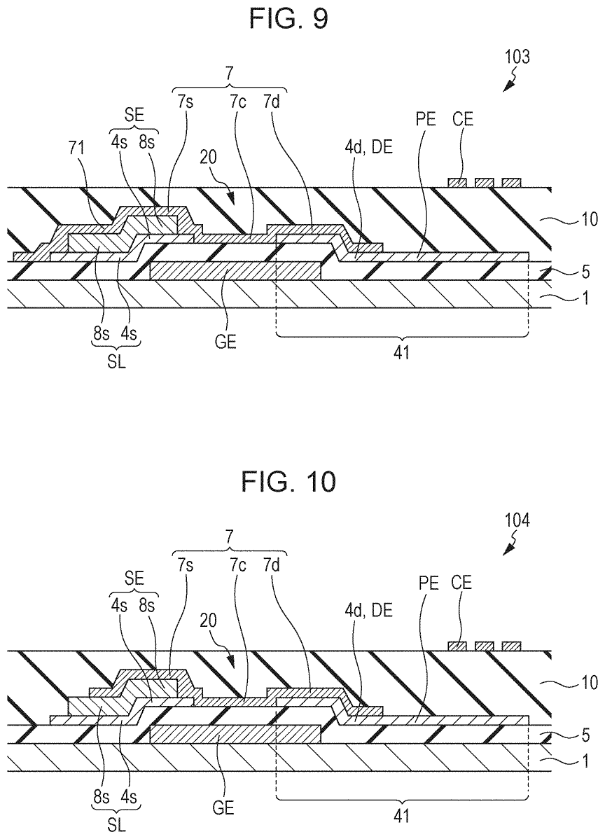

FIGS. 9 and 10 are cross-sectional views illustrating active matrix substrates 103 and 104 according to Modification 2, respectively.

The active matrix substrate 103 shown in FIG. 9 differs from the active matrix substrate 101 shown in FIGS. 2A and 2B in that the drain electrode DE of the TFT 20 includes the drain transparent conducting layer 4d formed from the first transparent conducting film but does not include a metal layer formed from the source conducting film. In this example, the drain electrode DE is a transparent electrode composed solely of the first transparent conducting film. The drain contact region 7d of the oxide semiconductor layer 7 is in direct contact with the upper surface of the drain electrode DE (drain transparent conducting layer 4d).

The active matrix substrate 104 shown in FIG. 10 differs from the active matrix substrate 102 shown in FIGS. 7A and 7B in that the drain electrode DE of the TFT 20 includes the drain transparent conducting layer 4d formed from the first transparent conducting film and does not include a metal layer formed from the source conducting film. As in the case of the example shown in FIG. 9, the drain electrode DE is a transparent electrode composed only of the first transparent conducting film, and the drain contact region 7d of the oxide semiconductor layer 7 may be in direct contact with the upper surface of the drain electrode DE (drain transparent conducting layer 4d).

The present modification makes it possible to further increase a pixel aperture ratio, as the drain electrode DE is a transparent electrode. The active matrix substrates 103 and 104 may each be manufactured by a method that is similar to that by which the active matrix substrates 101 and 102 are manufactured.

### Modification 3

An active matrix substrate according to Modification 3 differs from the aforementioned active matrix substrates in that the active matrix substrate according to Modification 3 does not include a common electrode. The active matrix substrate according to Modification 3 may be applied, for example, to a VA-mode display device.

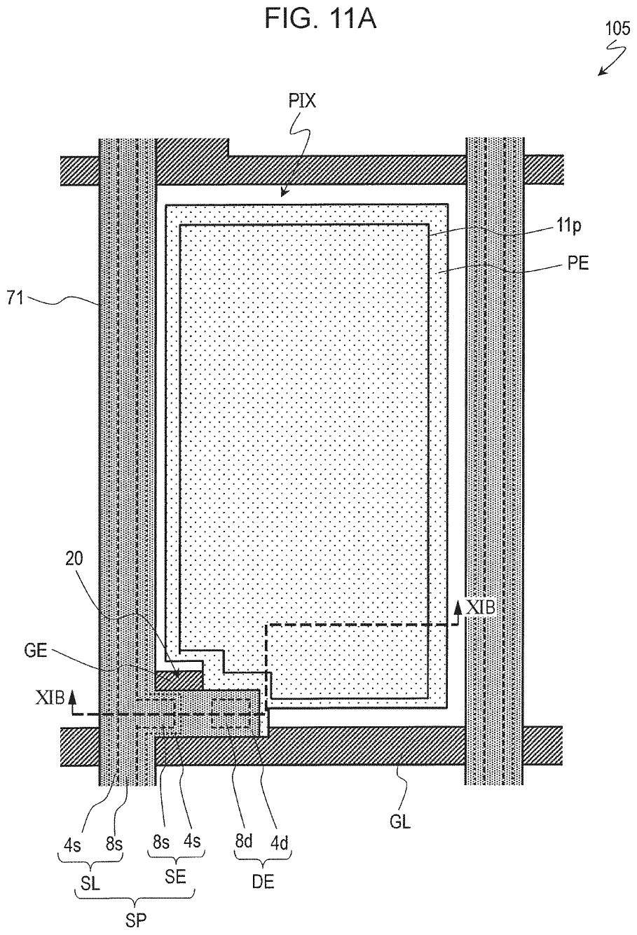

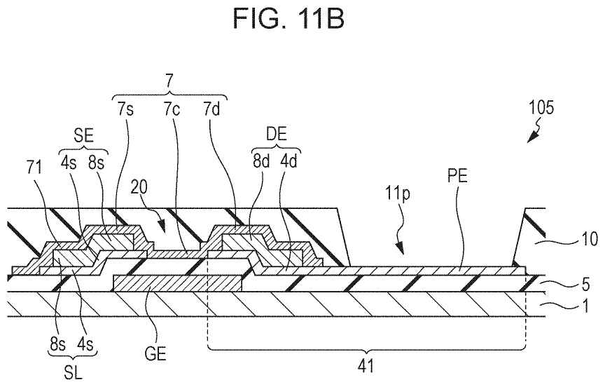

FIG. 11A is a plan view showing part of an active matrix substrate 105 according to Modification 3, and FIG. 11B is a cross-sectional view taken along line XIB-XIB shown in FIG. 11A.

The active matrix substrate 105 according to Modification 3 differs from the active matrix substrate 101 in that the active matrix substrate 105 does not have a common electrode and that the first insulating layer 10 is provided with an opening 11p through which the pixel electrode PE is exposed.

The active matrix substrate 105 may be manufactured by a method that is similar to that by which the active matrix substrate 101 is manufactured. Note, however, that the method for manufacturing an active matrix substrate 105 differs from the method for manufacturing an active matrix substrate 101 in that in the patterning of the first insulating layer 10, an opening 11p is formed in the first insulating layer 10 in each pixel region to expose part of the pixel electrode PE and the common electrode CE is not provided after that.

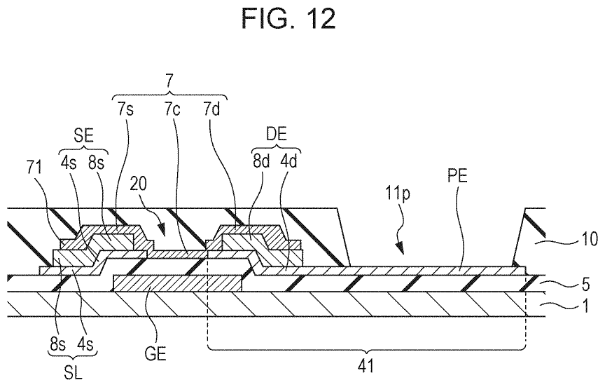

The foregoing configuration may be applied to the active matrix substrates (FIGS. 7A, 7B, 9, and 10) according to Modifications 1 and 2. For example, as illustrated in FIG. 12, parts of the metal layers 8s and 8d in the source metal layer do not need to be covered with the oxide semiconductor film (see FIGS. 7A and 7B). Alternatively, although not illustrated, the drain electrode DE is a transparent electrode composed only of the drain transparent conducting layer 4d and does not need to include a metal layer (see FIGS. 9 and 10).

### Regarding TFT Structure and Oxide Semiconductor

The TFT 20 may be a channel-etch TFT or may be an etch-stop TFT. In the “channel-etch TFT”, for example, as shown in FIG. 2, an etch stop layer is not formed on top of a channel region, and lower surfaces of ends of source and drain electrodes beside a channel are disposed so as to be in contact with an upper surface of an oxide semiconductor layer. The channel-etch TFT is formed, for example, by forming a conducting film on top of the oxide semiconductor layer for use in the source and drain electrodes and making a source-drain separation. In the source-drain separation process, a surface portion of a channel region may be etched. Meanwhile, in a TFT (etch-stop TFT) in which an etch stop layer is formed on top of a channel region, lower surfaces of ends of source and drain electrodes beside a channel are located, for example, on top of the etch stop layer. The etch-stop TFT is formed by forming an etch stop layer covering a portion of an oxide semiconductor layer that is to serve as a channel region, forming a conducting film on top of the oxide semiconductor layer and the etch stop layer for use in source and drain electrodes, and then making a source-drain separation. In this case, a photolithography process needs to be executed separately in the formation of the etch stop layer.

The oxide semiconductor of the oxide semiconductor layer 7 may be an amorphous oxide semiconductor or may be a crystalline oxide semiconductor having a crystalline portion. Examples of the crystalline oxide semiconductor include a polycrystalline oxide semiconductor, a microcrystalline oxide semiconductor, and a crystalline oxide semiconductor whose c axis is aligned substantially perpendicularly to a layer surface.

The oxide semiconductor layer 7 may have a stack structure of two or more layers. In a case where the oxide semiconductor layer 7 has a stack structure, the oxide semiconductor layer 7 may include an amorphous oxide semiconductor layer and a crystalline oxide semiconductor layer. Alternatively, the oxide semiconductor layer 7 may include a plurality of crystalline oxide semiconductor layers of different crystal structures. Further, the oxide semiconductor layer 7 may include a plurality of amorphous oxide semiconductor layers. In a case where the oxide semiconductor layer 7 has a two-layer structure including an upper layer and a lower layer, it is preferable that the energy gap of an oxide semiconductor contained in the upper layer be greater than the energy gap of an oxide semiconductor contained in the lower layer. Note, however, that in a case where the difference in energy gap between these layers is comparatively small, the energy gap of the oxide semiconductor of the lower layer may be greater than the energy gap of the oxide semiconductor of the upper layer.

Materials for amorphous oxide semiconductors and each of the aforementioned crystalline oxide semiconductors, structures thereof, method for forming films thereof, the configuration of an oxide semiconductor layer having a stack structure, or other features are described, for example, in Japanese Unexamined Patent Application Publication No. 2014-007399. The entire contents of Japanese Unexamined Patent Application Publication No. 2014-007399 are hereby incorporated by reference.

The oxide semiconductor layer 7 may contain at least one type of metal element of, for example, In, Ga, and Zn. In the present embodiment, the oxide semiconductor layer 7 contains, for example, an In—Ga—Zn—O semiconductor (e.g. indium-gallium-zinc oxide). Note here that an In—Ga—Zn—O semiconductor is a ternary oxide of In (indium), Ga (gallium), and Zn (zinc), and examples of proportions (composition ratios) of In, Ga, and Zn include, but are not limited to, In:Ga:Zn=2:2:1, In:Ga:Zn=1:1:1, and In:Ga:Zn=1:1:2. Such an oxide semiconductor layer 7 may be formed from an oxide semiconductor film containing an In—Ga—Zn—O semiconductor.

An In—Ga—Zn—O semiconductor may be amorphous or may be crystalline. A preferable crystalline In—Ga—Zn—O semiconductor is a crystalline In—Ga—Zn—O semiconductor whose c axis is aligned substantially perpendicularly to a layer surface.

Note that the crystal structure of a crystalline In—Ga—Zn—O semiconductor is disclosed, for example, in the aforementioned Japanese Unexamined Patent Application Publication No. 2014-007399, Japanese Unexamined Patent Application Publication No. 2012-134475, Japanese Unexamined Patent Application Publication No. 2014-209727, or patent literatures. The entire contents of Japanese Unexamined Patent Application Publication No. 2012-134475 and Japanese Unexamined Patent Application Publication No. 2014-209727 are hereby incorporated by reference. A TFT having an In—Ga—Zn—O semiconductor layer has high mobility (more than 20 times higher than that of an a-Si TFT) and a low leak current (less than 1/100 of that of an a-Si TFT) and is therefore suitably used as a driving TFT (e.g. a TFT included in a driving circuit provided around a display region including a plurality of pixels and on top of the same substrate as the display region) and a pixel TFT (i.e. a TFT provided in a pixel).

The oxide semiconductor layer 7 may contain another oxide semiconductor instead of the In—Ga—Zn—O semiconductor. For example, the oxide semiconductor layer 7 may contain an In—Sn—Zn—O semiconductor (e.g. In₂O₃—SnO₂—ZnO; InSnZnO). The In—Sn—Zn—O semiconductor is a ternary oxide of In (indium), Sn (tin), and Zn (zinc). Alternatively, the oxide semiconductor layer 7 may contain an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, CdO (cadmium oxide), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, an In—Ga—Zn—Sn—O semiconductor, or other semiconductors.

Note that the pixel electrode PE may have the same composition and crystalline structure as the oxide semiconductor layer 7. In a case where the oxide semiconductor layer 7 has a stack structure, the pixel electrode PE may have a stack structure that is similar to that of the oxide semiconductor layer 7.

An active matrix substrate according to an embodiment of the present disclosure is widely applicable to display devices such as liquid crystal display devices, organic electroluminescence (EL) display devices, and inorganic electroluminescence display devices, imaging devices such as image sensor devices, electronic devices such as image input devices and fingerprint reading devices, or other devices.

The present disclosure contains subject matter related to that disclosed in U.S. Provisional Patent Application No. 63/286,639 filed in the USPTO on Dec. 7, 2021, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An active matrix substrate having a display region including a plurality of pixel regions, the active matrix substrate comprising:
a substrate;
a plurality of thin-film transistors, supported on the substrate and associated with the plurality of pixel regions;
a plurality of pixel electrodes disposed in the plurality of pixel regions; and
a first insulating layer located above the plurality of thin-film transistors and the plurality of pixel electrodes,
wherein
each of the pixel electrodes is formed from a transparent conducting material,
each of the thin-film transistors includes a gate electrode, a gate insulating layer covering the gate electrode, source and drain electrodes placed at a distance from each other on top of the gate insulating layer, and an oxide semiconductor layer,
the oxide semiconductor layer includes a channel region that is in contact with the gate insulating layer between the source electrode and the drain electrode, a source contact region that is in contact with at least part of an upper surface of the source electrode, and a drain contact region that is in contact with at least part of an upper surface of the drain electrode,
the source electrode has a stack structure including a source transparent conducting layer formed at a layer that is identical to that at which each of the pixel electrodes is formed and a source metal layer disposed on top of part of an upper surface of the source transparent conducting layer and formed from a metal material,
the drain electrode includes a drain transparent conducting layer formed at a layer that is identical to that at which each of the pixel electrodes is formed, and
the drain transparent conducting layer is formed integrally with a corresponding one of the plurality of pixel electrodes.

2. The active matrix substrate according to claim 1, wherein the drain electrode includes the drain transparent conducting layer and a drain metal layer disposed on top of part of an upper surface of the drain transparent conducting layer and formed at a layer that is identical to that at which the source metal layer is formed.

3. The active matrix substrate according to claim 1, further comprising:
a plurality of source bus lines extending in a row-wise direction; and
a plurality of gate bus lines extending in a column-wise direction,
wherein
each of the source bus lines has the stack structure including the source transparent conducting layer and the source metal layer, and
the source electrode of each of the thin-film transistors is formed integrally with a corresponding one of the plurality of source bus lines.

4. The active matrix substrate according to claim 3, further comprising a plurality of wire covering layers formed at a layer that is identical to that at which the oxide semiconductor layer of each of the thin-film transistors is formed,
wherein each of the wire covering layer covers one of the plurality of source bus lines and extends in the column-wise direction.

5. The active matrix substrate according to claim 1, wherein upper and side surfaces of the source metal layer are covered with the oxide semiconductor layer or a covering layer formed at a layer identical to that at which the oxide semiconductor layer is formed.

6. The active matrix substrate according to claim 1, wherein
part of an end face of the oxide semiconductor layer of each of the thin-film transistors is located on an upper surface of the source metal layer, and
part of the upper surface of the source metal layer is in direct contact with the first insulating layer.

7. The active matrix substrate according to claim 1, further comprising a common electrode disposed on top of the first insulating layer,
wherein when seen from a direction normal to the substrate, the common electrode partially overlaps the plurality of pixel electrodes via the first insulating layer.

8. The active matrix substrate according to claim 1, wherein in each of the pixel regions, the first insulating layer has an opening through which part of each of the pixel electrodes is exposed.

9. The active matrix substrate according to claim 1, further comprising a plurality of terminals disposed in a non-display region other than the display region,
wherein each of the terminals includes
a source connection including a connection transparent conducting layer formed at a layer that is identical to that at which each of the pixel electrodes is formed and a connection metal layer disposed on top of part of an upper surface of the connection transparent conducting layer and formed at a layer that is identical to that at which the source metal layer is formed,
a connection covering layer, formed at a layer that is identical to that at which the oxide semiconductor layer of each of the thin-film transistors is formed, that covers part of an upper surface and side surfaces of the source connection,
an extension of the first insulating layer provided on top of the connection covering layer,
a contact hole, formed in the first insulating layer and the connection covering layer, through which part of the source connection is exposed, and
an upper connection that is in contact with the part of the source connection in the contact hole.

10. The active matrix substrate according to claim 6, further comprising a plurality of terminals disposed in a non-display region other than the display region,
wherein each of the terminals includes
a source connection including a connection transparent conducting layer formed at a layer that is identical to that at which each of the pixel electrodes is formed and a connection metal layer disposed on top of part of an upper surface of the connection transparent conducting layer and formed at a layer that is identical to that at which the source metal layer is formed,
an extension of the first insulating layer provided on top of the source connection,
a contact hole, formed in the first insulating layer, through which part of the source connection is exposed, and
an upper connection that is in contact with the part of the source connection in the contact hole.

11. The active matrix substrate according to claim 1, wherein the first insulating layer does not include an organic insulating film.

12. The active matrix substrate according to claim 1, wherein the oxide semiconductor layer contains an In—Ga—Zn—O semiconductor.

13. The active matrix substrate according to claim 12, wherein the In—Ga—Zn—O semiconductor includes a crystalline portion.

14. A method for manufacturing an active matrix substrate including a plurality of source bus lines, a plurality of gate bus lines, a plurality of thin-film transistors, and a plurality of pixel electrodes, the method comprising:
(a) forming, on top of a substrate, gate electrodes of the plurality of thin-film transistors and the plurality of gate bus lines;
(b) forming a gate insulating layer on top of the gate electrodes of the plurality of thin-film transistors and the plurality of gate bus lines;
(c) forming a first transparent conducting film on top of the gate insulating layer and forming a source conducting film on top of the first transparent conducting film;
(d) patterning the first transparent conducting film and the source conducting film by one photolithography process with a multi-tone mask and thereby forming the plurality of source bus lines, source and drain electrodes of the plurality of thin-film transistors, and the plurality of pixel electrodes, the plurality of source bus lines and the source electrodes having a stack structure including the first transparent conducting film and the source conducting film, the drain electrodes including at least the first transparent conducting film, the plurality of pixel electrodes including the first transparent conducting film but not including the source conducting film; and
(e) after (d), forming and patterning an oxide semiconductor film and thereby forming a plurality of oxide semiconductor layers that are to serve as active layers of the plurality of thin-film transistors.

15. The method according to claim 14, wherein
in (e), the oxide semiconductor film is patterned with an etchant containing phosphoric acid, nitric acid, and acetic acid, and
a portion of the oxide semiconductor film, patterned in (d), that entirely covers side and upper surfaces of the source conducting film is left without being removed.

16. The method according to claim 14, wherein (e) further includes patterning the oxide semiconductor film and thereby forming a plurality of wire coverings separately covering each of the plurality of source bus lines.

17. The method according to claim 14, wherein the oxide semiconductor film contains an In—Ga—Zn—O semiconductor.

18. The method according to claim 17, wherein the In—Ga—Zn—O semiconductor includes a crystalline portion.
